(19) United States
(12) Patent Application Publication
(10) Pub. No.: US 2018/0354175 A1
(43) Pub. Date: Dec. 13, 2018

(54) ELECTRONIC EQUIPMENT HOUSING

(71) Applicant: Sumitomo Chemical Company, Limited, Tokyo (JP)

(72) Inventor: Shintaro KOMATSU, Tsukuba-shi, Ibaraki (JP)

(73) Assignee: Sumitomo Chemical Company, Limited, Tokyo (JP)

(21) Appl. No.: 15/757,818

(22) PCT Filed: Sep. 7, 2016
(86) PCT No.: PCT/JP2016/076289

§ 371 Date: Mar. 6, 2018

(30) Foreign Application Priority Data
Sep. 11, 2015 (JP) 2015-179990

(51) Int. Cl. B29C 45/27; C08L 67/03; C08K 7/02; C08J 5/00; H05K 5/02

(52) U.S. Cl. CPC B29C 45/27; C08L 67/03; H05K 5/02; C08J 5/00; C08K 7/02

(57) ABSTRACT

Provided is an electronic equipment housing obtained by injection molding of a resin composition including liquid crystal polyester and a filling material. In the electronic equipment housing, a projected area per filling gate mark obtained by dividing a projected area of the electronic equipment housing by the number of filling gate marks of the resin composition on a surface of the electronic equipment housing is equal to or greater than 100 cm². In the electronic equipment housing, a ratio obtained by dividing the projected area (cm²) per filling gate mark by an average thickness (cm) of the electronic equipment housing is equal to or greater than 1,000. In the electronic equipment housing, the average thickness is greater than 0.01 cm and equal to or smaller than 0.2 cm. The liquid crystal polyester has one or more repeating units selected from the group represented by specific formulae.

### TECHNICAL FIELD

The present invention relates to an electronic equipment housing.

Priority is claimed on Japanese Patent Application No. 2015-179990, filed on Sep. 11, 2015, the content of which is incorporated herein by reference.

### BACKGROUND ART

Thin and light-weight products are strongly required in the market along with spreading of electronic equipment represented by portable information terminals such as notebook PCs (laptops), smartphones, and tablet equipment. Along with this, even electronic equipment housings configuring the products are strongly required to have thin-wall forming properties and lightness, and satisfy sufficient strength, from a viewpoint of protecting internal electronic components.

From a viewpoint of realizing thin-wall forming properties and lightness, plastic materials are used as materials for the electronic equipment housings.

PTL 1, for example, discloses an electronic equipment housing obtained by injection molding by using an acrylonitrile-butadiene-styrene copolymer-based (ABS) resin, a polycarbonate-based (PC) resin, a mixed resin of an ABS-based resin and a PC-based resin, a mixed resin of a nylon-based resin and a polyphenylene sulfide-based (PPS) resin, a mixed resin of an ABS-based resin and a polybutylene terephthalate-based (PBT) type resin, a liquid crystal polyester-based (LCP) type resin, or the like.

### CITATION LIST

### Patent Literature

[PTL 1] Japanese Unexamined Patent Application, First Publication No. H07-60777

### SUMMARY OF INVENTION

### Technical Problem

In the injection molding, a thin line (weld line) is generated at a part of a die where flows of a molten resin join and are fused. Particularly, in a case where it is necessary to provide two or more gates, generation of weld lines is unavoidable. This weld line is the reason for having poor appearance or a decrease in strength due to poor fusion. In an electronic equipment housing of the related art obtained by using a resin having insufficient fluidity, a plurality of gates are necessarily provided in a case of performing the injection molding. Accordingly, as the number of gates used increases, a large number of weld lines are generated. As a result, the strength of the molded electronic equipment housing deteriorates.

The invention is made in consideration of these circumstances and an object thereof is to provide an electronic equipment housing having a decreased number of weld lines and excellent strength even with a thin thickness.

### Solution to Problem

An electronic equipment housing according to the embodiment of the invention is as follows.

[1] an electronic equipment housing obtained by injection molding of a resin composition including liquid crystal polyester and a fibrous filling material, in which a projected area per gate filled with the resin composition is equal to or greater than 100 cm², a ratio of the projected area (cm²) per gate and an average thickness (cm) of the electronic equipment housing is equal to or greater than 1,000, the average thickness of the electronic equipment housing is greater than 0.01 cm and equal to or smaller than 0.2 cm, and the resin composition includes liquid crystal polyester having a repeating unit represented by General Formulae (1), (2), and (3), and a filling material.

—O—Ar¹—CO— (1)

—CO—Ar²—CO— (2)

—X—Ar³—Y— (3)

(in the formulae, Ar¹ is a phenylene group, a naphthylene group, or a biphenylylene group; Ar² and Ar³ are each independently a phenylene group, a naphthylene group, a biphenylylene group, or a group represented by General Formula (4); X and Y are each independently an oxygen atom or an imino group; and one or more hydrogen atoms in Ar¹, Ar², and Ar³ may be each independently substituted with a halogen atom, an alkyl group, or an aryl group)

—Ar⁴—Z—Ar⁵— (4)

(in the formula, Ar⁴ and Ar⁵ are each independently a phenylene group or a naphthylene group; and Z is an oxygen atom, a sulfur atom, a carbonyl group, a sulfonyl group, or an alkylidene group)

In addition, the embodiment of the invention also has the following aspect.

[1A] An electronic equipment housing obtained by injection molding of a resin composition including liquid crystal polyester and a filling material, in which a projected area per filling gate mark obtained by dividing a projected area of the electronic equipment housing by the number of filling gate marks of the resin composition on a surface of the electronic equipment housing is equal to or greater than 100 cm², a ratio obtained by dividing the projected area (cm²) per filling gate mark by an average thickness (cm) of the electronic equipment housing is equal to or greater than 1,000, the average thickness of the electronic equipment housing is greater than 0.01 cm and equal to or smaller than 0.2 cm, and the liquid crystal polyester has one or more repeating units selected from the group represented by General Formulae (1), (2), and (3).

—O—Ar¹—CO— (1)

—CO—Ar²—CO— (2)

—X—Ar³—Y— (3)

(in the formulae, Ar¹ is a phenylene group, a naphthylene group, or a biphenylylene group; Ar² and Ar³ are each independently a phenylene group, a naphthylene group, a biphenylylene group, or a group represented by General Formula (4); X and Y are each independently an oxygen atom or an imino group; and one or more hydrogen atoms in Ar¹, Ar², and Ar³ may be each independently substituted with a halogen atom, an alkyl group, or an aryl group or may not be substituted) [2A] A manufacturing method of an electronic equipment housing obtained by injection molding of a resin composition including liquid crystal polyester having one or more repeating units selected from the group represented by General Formulae (1), (2), and (3), and a filling material, the method including: filling a die in which a projected area per gate of the die obtained by dividing a projected area (cm²) of the electronic equipment housing by the number of gates of the die is equal to or greater than 100 cm², a ratio obtained by dividing the projected area per gate of the die by an average thickness (cm) of the electronic equipment housing is equal to or greater than 1,000, and the average thickness of the electronic equipment housing is greater than 0.01 cm and equal to or smaller than 0.2 cm, with the resin composition in a molten state; and cooling and solidifying the resin composition.

—O—Ar¹—CO— (1)

—CO—Ar²—CO— (2)

—X—Ar³—Y— (3)

(in the formulae, Ar¹ is a phenylene group, a naphthylene group, or a biphenylylene group; Ar² and Ar³ are each independently a phenylene group, a naphthylene group, a biphenylylene group, or a group represented by General Formula (4); X and Y are each independently an oxygen atom or an imino group; and one or more hydrogen atoms in Ar¹, Ar², and Ar³ may be each independently substituted with a halogen atom, an alkyl group, or an aryl group or may not be substituted)

—Ar⁴—Z—Ar⁵— (4)

(in the formula, Ar⁴ and Ar⁵ are each independently a phenylene group or a naphthylene group; and Z is an oxygen atom, a sulfur atom, a carbonyl group, a sulfonyl group, or an alkylidene group)

### Advantageous Effects of Invention

According to the invention, it is possible to provide an electronic equipment housing having a decreased number of weld lines and excellent strength even with a thin thickness.

### BRIEF DESCRIPTION OF DRAWINGS

FIG. 1 is a schematic view showing an example of an electronic equipment housing of the embodiment.

FIG. 2 is a view showing a PC housing of an example.

FIG. 3A is a view showing positions of gates in a case where the number of gates of the PC housing of the example is 4.

FIG. 3B is a perspective view showing the positions of the gates of the PC housing of FIG. 3A.

FIG. 4A is a view showing positions of gates in a case where the number of gates of the PC housing of the example is 3.

FIG. 4B is a perspective view showing the positions of the gates of the PC housing of FIG. 4A.

FIG. 5A is a view showing positions of gates in a case where the number of gates of the PC housing of the example is 12.

FIG. 5B is a perspective view showing the positions of the gates of the PC housing of FIG. 5A.

FIG. 6 is a view showing cut-off positions of test pieces of the PC housing of the example.

FIG. 7A is a schematic perspective view showing a position where a jig is pressed against a test piece A in a bend elastic modulus test of the example.

FIG. 7B is a schematic perspective view showing a position where a jig is pressed against a test piece B in a bend elastic modulus test of the example.

### DESCRIPTION OF EMBODIMENTS

<Electronic Equipment Housing>

An electronic equipment housing of the embodiment will be described.

The electronic equipment housing of the embodiment is a housing configuring electrical and electronic equipment, for example, a housing configuring various items of electronic equipment represented by portable information terminals such as notebook PCs (PC here is also referred to as a personal computer), smartphones, or tablet equipment. The electronic equipment housing of the embodiment particularly indicates one of components configuring an outer surface of the electronic equipment and further particularly indicates a component having a projected area equal to or greater than 100 cm² which will be described later among such components.

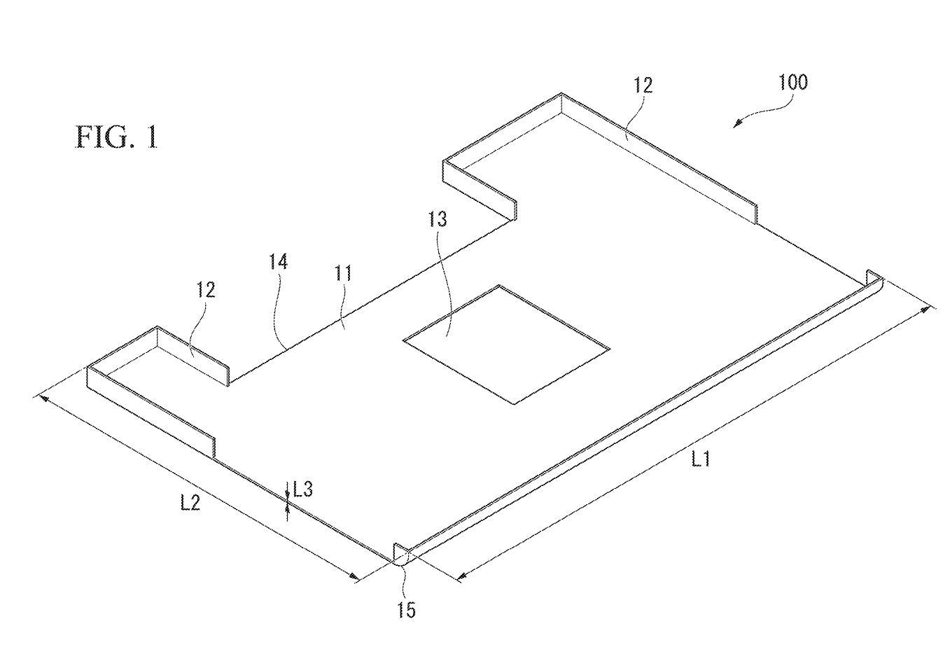

FIG. 1 shows a housing 100 of a notebook PC as an example of the electronic equipment housing of the embodiment. The housing 100 is schematically configured to include a plate 11 and a margin plate 12 extending approximately vertically to at least a part of the margin of the plate 11. The plate 11 includes a hole 13 through which other members can be inserted. The housing includes a cut-out 14 along one long side, used for connection with other members and the like. A curved-surface margin plate 15 which forms a curved-surface shape and extends approximately vertically to the plate 11 is provided on a long side of the housing opposite to the side provided with the cut-out 14. In the housing 100 of the notebook PC shown in FIG. 1, a size L1 of the housing in a longitudinal direction is approximately 20 cm to 40 cm, and a size L2 of the housing in a short direction (excluding the curved-surface margin plate) is approximately 20 cm to 30 cm. In addition, a size L3 of an average thickness of the housing is 0.01 cm to 0.2 cm. The size L3 of the average thickness of the housing is preferably 0.01 cm to 0.18 cm and more preferably 0.03 cm to 0.15 cm.

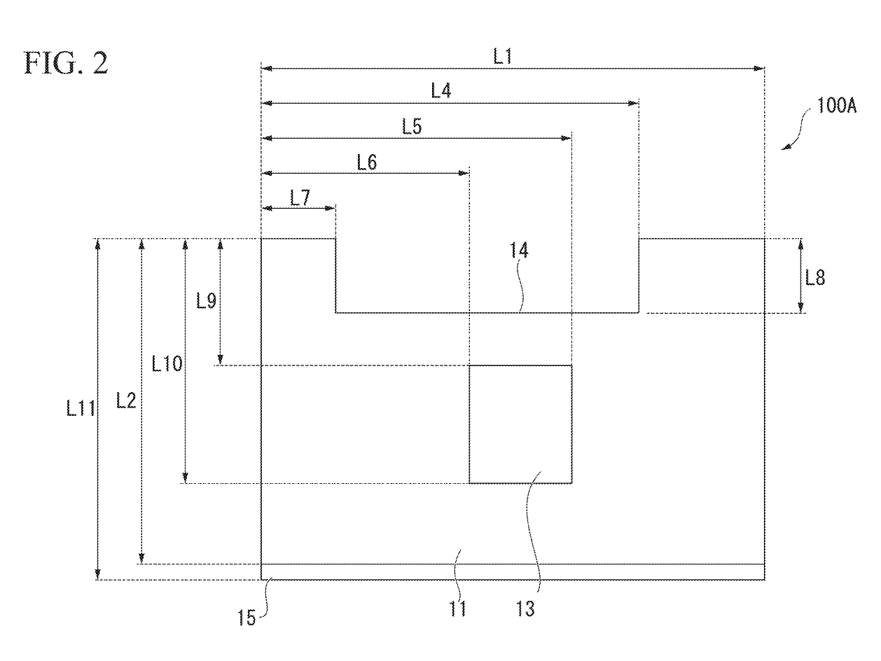

In a case where a more preferable range is shown in FIG. 2, a distance L4 to an end portion of the cut-out 14 on a side far away from the end portion of the short side of the housing (left end portion in the drawing) is preferably 200 to 300 mm. A distance L5 to an end portion of the hole 13 on a side far away from the end portion of the short side of the housing is preferably 160 to 260 mm. A distance L6 to an end portion of the hole 13 on a side close to the end portion of the short side of the housing is preferably 90 to 190 mm. A distance L7 to an end portion of the cut-out 14 close to the end portion of the short side of the housing is preferably 10 to 100 mm. A width L8 of the cut-out 14 is preferably 10 to 100 mm. A distance L9 to an end portion of the hole 13 close to an end portion of a long side of the housing (upper end portion in the drawing) is preferably 35 to 135 mm. A distance L10 to an end portion of the hole 13 far away from the end portion of the long side of the housing is preferably 115 to 215 mm. A size L11 of the housing including the plate 11 and the curved-surface margin plate 15 is preferably 210 to 420 mm. These can be set in the ranges of L1 to L3 which are sizes of the housing. In the embodiment, the sizes of the electronic equipment housing are not limited to the values described above and can be suitably designed.

The “average thickness” is a value obtained by measuring the thicknesses of the plate 11 of the electronic equipment housing 100 at plural points (for example, 10 to 40 random points on the plate 11 other than the margin plate 12 or the cut-out 13) and calculating the arithmetic mean value thereof.

In this specification, the “projected area” is a measure indicating a dimension (size) of the electronic equipment housing. In a case where the electronic equipment housing has a complicated shape or the like, the dimension thereof can be converted into and shown as the projected area (unit: cm²). More specifically, the projected area is an area of a shadow cast on a plane perpendicular to a vertical direction, in a case where an upper surface of the electronic equipment housing is irradiated with a parallel ray from the vertical direction.

The electronic equipment housing of the embodiment is obtained by injection molding of a specific resin composition. The injection molding is a molding method of injecting, cooling, and solidifying a melted resin material in a die having a plurality of gates, and extracting a molded body.

The electronic equipment housing of the embodiment is molded by adjusting the number of gates and disposition of the gates, so that a projected area per gate filled with the resin composition at the time of the injection molding becomes the area described above, regarding the projected area of the molded electronic equipment housing. Here, in the molded electronic equipment housing, the number of gates of the die of the embodiment and the disposition of the gates of the die can be measured from filling gate marks which will be described later. The number of gates of the die is calculated so that the projected area per gate is equal to or greater than 100 cm², in a case where the projected area of the molded electronic equipment housing is divided by the number of gates, and may be suitably adjusted in accordance with the shape of the molded electronic equipment housing. By setting the projected area per gate of the die to be equal to or greater than 100 cm², it is possible to reduce the number of gates and prevent generation of weld lines.

In the embodiment, the projected area per gate of the die is preferably equal to or greater than 110 cm² and more preferably equal to or greater than 120 cm². The upper limit of the projected area per gate of the die is particularly limited, and is preferably equal to or smaller than 600 cm², and more preferably equal to or smaller than 450 cm². That is, the projected area per gate of the die can be selected from a range of 110 to 600 cm² and preferably in a range of 120 to 450 cm².

The disposition of positions of the gates of the die may be suitably adjusted according to the shape of the molded electronic equipment housing and is not particularly limited. However, in a case where two or more gates are provided, a weld line is generated in the position where flows of molten resin join in the die. For example, in a case where the weld line is formed in a linear line shape so as to cross the electronic equipment housing, this may be a reason for having a decrease in strength. In order to prevent a decrease in strength of the electronic equipment housing, the disposition of positions of the gates of the die is suitably adjusted by considering the directions of flows of the molten resin and the like, so that the number and/or sizes of the weld line are minimized. As a method for selecting a positional relationship, the positions of the gates are set so that the plurality of gates are evenly dispersed as much as possible on the surface of the electronic equipment housing.

In a case of setting the positions of the gates, the positions of the gates may be set so that the conditions described above are obtained, by simulating flows of the molten resin in advance by using various softwares of CAE (flow analysis simulation). In addition, the number of gates described above may also be set in accordance with the disposition from the flows of the molten resin.

As a rough estimate, the distance between gates is preferably two times or less of a distance of flow from the injection of the molten resin from the gate of the die to the flowing of the molten resin until the die is filled therewith. As conditions affecting the distance of flow, the thickness of the electronic equipment housing is exemplified, in addition to the composition of the resin or the temperature. Thus, the distance between gates is set in accordance with the design of the electronic equipment housing (composition of the resin, the temperature, the thickness of the electronic equipment housing, and the like) which will be described later.

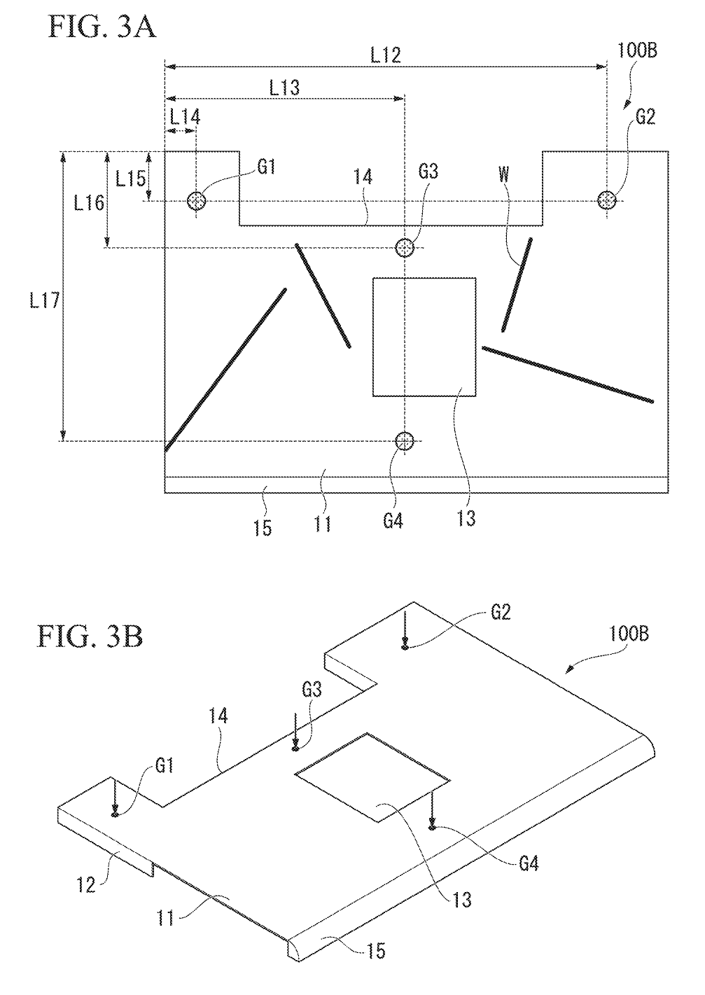

As a specific example of the positions of the gates of the die, a case in which four gates of the die are provided, gates G1 and G2 are provided close to a short side of the housing and a gate G3 is provided to be adjacent to the cut-out 14 along a long side of the housing which is a side provided with the cut-out 14, and a gate G4 is provided along a long side which is a side without the cut-out 14 is shown, for example, as shown in FIG. 3A. In FIG. 3A, the positions of the gates are shown with positions of gate marks on the surface of the housing. A distance L14 between the gate G1 and a short side adjacent to the gate G1 (short side on the left side of the drawing) is preferably 10 to 20 mm. A distance L15 between the gate G1 and a short side adjacent to the gate G1 is preferably 35 to 55 mm. A distance L12 between the gate G2 and the short side is preferably 290 to 310 mm. In the example shown in the drawing, the distance between the gate G2 and the adjacent short side is L15, in the same manner as the distance regarding the gate G1, and values other than 35 to 55 mm may be selected. A distance L13 between the gate G3 to the short side is 100 to 200 mm, and a distance L16 between the gate G3 and the long side is preferably 60 to 70 mm. In the example shown in the drawing, the distance between the gate G4 and the short side is L13, in the same manner as the distance regarding the gate G3, and values other than 100 to 200 mm may be selected. The distance between the gate G4 and the long side is preferably 150 to 250 mm. These can be set in the range of L1 to L3 which are the sizes of the housing.

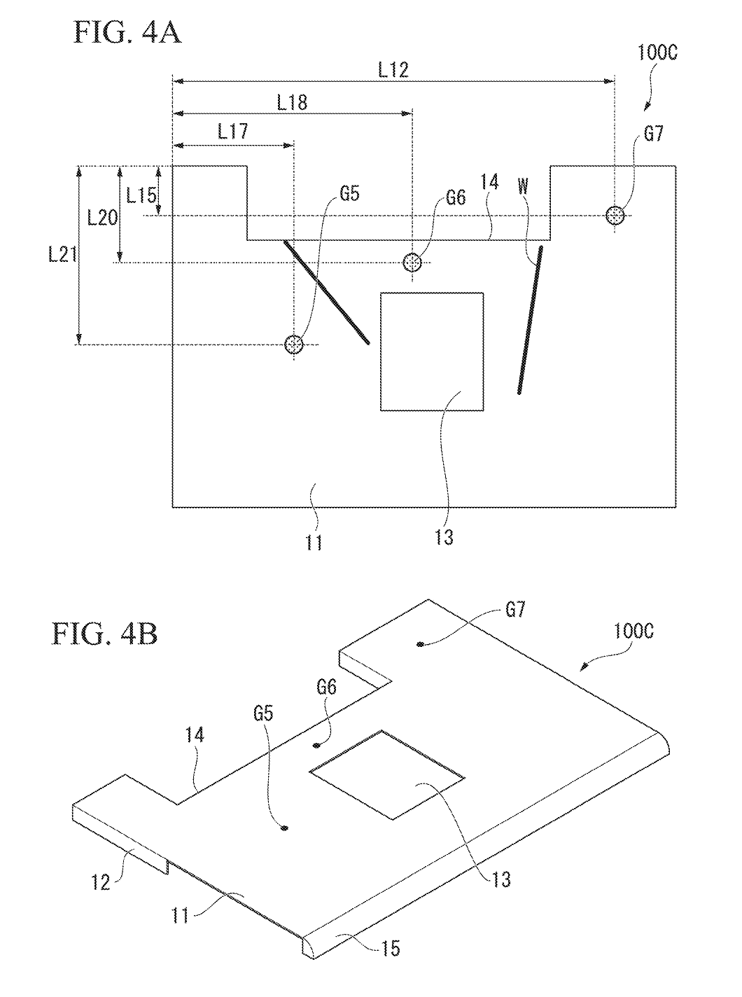

As another specific example of the positions of the gates of the die, a case in which three gates of the die are provided, a gate G5 is provided on the plate 10, a gate G6 is provided to be adjacent to the cut-out 14, and a gate G7 is provided close to a short side of the housing is shown, for example, as shown in FIG. 4A. A distance L17 between the gate G5 and a short side close to the gate G5 (side on the left side in the example shown in the drawing) is preferably 50 to 140 mm. A distance L21 between the gate G5 and a long side close to the gate G5 (side on the upper side in the example shown in the drawing) is preferably 85 to 185 mm. A distance L18 between the gate G6 and the short side is preferably 100 to 200 mm. A distance L20 between the gate G6 and the long side is preferably 60 to 80 mm. The position of the gate G7 may be selected from the ranges of the L12 and L15.

The number and the positions of the gates of the die for manufacturing the molded electronic equipment housing can be estimated from the number and positions of filling gate marks on the electronic equipment housing. Accordingly, a projected area per gate of the die of the molded electronic equipment housing can be calculated by dividing the projected area of the electronic equipment housing by the number of filling gate marks.

Here, the filling gate mark is a mark generated in a case where the resin composition is injected from the gate of the die and the die is filled with the resin composition, for the molding of the electronic equipment housing. The filling gate mark can be recognized from the surface of the molded electronic equipment housing.

In addition, as the types of the gate disposed on the die, pin point gates (pin gates), submarine gates, or the like may be used. Further, a gate diameter is not particularly limited, and is normally 0.1 to 5 mm, particularly 0.2 to 4 mm, and especially preferably 0.3 to 3.5 mm.

The electronic equipment housing of the embodiment is a thin housing satisfying the condition in which the ratio of the projected area (cm²) per gate and the average thickness (cm) of the electronic equipment housing is equal to or greater than 1,000. In this specification, the ratio of the projected area (cm²) and the average thickness (cm) can also be shown as a size (cm) obtained by dividing the projected area (cm²) per gate by the average thickness (cm) of the electronic equipment housing. In the embodiment, the ratio of the projected area and the average thickness (cm) of the electronic equipment housing is preferably equal to or greater than 1,100 and more preferably equal to or greater than 1,200. The upper limit of the ratio is not particularly limited, and is, for example, preferably equal to or smaller than 1,800 and more preferably equal to or smaller than 1,600. That is, the ratio of the projected area and the average thickness (cm) of the electronic equipment housing can be selected from 1,100 to 1,800 and preferably 1,200 to 1,600.

In Table 1, examples of general dimensions and projected areas of housings of a 15-inch notebook PC, a 14-inch notebook PC, portable terminals 1 to 2, and an 8-inch tablet are shown as examples of the electronic equipment housing. In addition, examples of the number of gates in a case of molding each electronic equipment housing in the embodiment and the projected area per gate (here, value obtained by dividing the projected area of each housing by the number of gates of the die in a case of molding the housing) are shown.

TABLE 1

| | Dimension | | | Projected |
|---|---|---|---|---|
| | (long side × | Projected | Number | area |
| | short side) | area | of | per gate |
| | (cm) | (cm²) | gates | (cm²) |
| 15-inch notebook PC | 37 × 26 | 962 | 6 | 160 |
| 14-inch notebook PC | 34 × 23 | 782 | 4 | 196 |
| portable tenninal 1 | 24 × 17 | 408 | 3 | 136 |
| portable terminal 2 | 20 × 14 | 280 | 2 | 140 |
| 8-inch tablet | 21 × 12 | 252 | 2 | 126 |

As shown in Table 1, the electronic equipment housing of the embodiment can be molded with a small number of gates which are 6 gates, even in a case of the 15-inch notebook PC. Accordingly, it is possible to provide an electronic equipment housing having a decreased number of weld lines and excellent strength even with a thin thickness.

In Table 2, examples of a projected area (cm²) per gate of a 15-inch notebook PC, a 14-inch notebook PC, portable terminals 1 to 2, and an 8-inch tablet, an average thickness of each electronic equipment housing, and examples of a ratio of the projected area and the average thickness (cm) are shown as examples of the electronic equipment housing.

TABLE 2

| | Projected | | Rate of projected |
|---|---|---|---|
| | area | Average | area and |
| | per gate | thickness | average |
| | (cm²) | (cm) | thickness |
| 15-inch notebook PC | 160 | 0.13 | 1231 |
| 14-inch notebook PC | 196 | 0.13 | 1508 |
| portable terminal 1 | 136 | 0.1 | 1360 |
| portable terminal 2 | 140 | 0.1 | 1400 |
| 8-inch tablet | 126 | 0.1 | 1260 |

As shown in Table 2, the electronic equipment housing of the embodiment is a thin housing in which the ratio of the projected area per gate and the average thickness (cm) of the electronic equipment housing is in a range of 1,000 to 1,600. As shown in the drawing, the embodiment can be suitably used for an electronic equipment housing having the ratio of 1,200 to 1,550.

The electronic equipment housing of the embodiment becomes a thin housing having a decreased number of weld lines, by setting the projecting area per gate to be equal to or greater than 100 cm², and satisfying the condition in which a size obtained by dividing the projected area by the average thickness (cm) of the electronic equipment housing is equal to or greater than 1,000 cm. Accordingly, it is possible to provide a housing satisfying a thin thickness, lightness, space saving, and excellent strength.

<<Resin Composition>>

The resin composition used for molding the electronic equipment housing of the embodiment will be described.

In the embodiment, the resin composition includes liquid crystal polyester having a repeating unit represented by one or more formulae selected from the group consisting of General Formulae (1), (2), and (3), and a filling material.

(Liquid Crystal Polyester)

The liquid crystal polyester used in the embodiment has a repeating unit represented by General Formula (1), (2), or (3).

—O—Ar¹—CO— (1)

—CO—Ar²—CO— (2)

—X—Ar³—Y— (3)

(In the formulae, Ar¹ is a phenylene group, a naphthylene group, or a biphenylylene group; Ar² and Ar³ are each independently a phenylene group, a naphthylene group, a biphenylylene group, or a group represented by General Formula (4); X and Y are each independently an oxygen atom or an imino group; and Ar¹, Ar², and Ar³ include those in which one or more hydrogen atoms in Ar¹, Ar², and Ar³ are each independently substituted a halogen atom, an alkyl group, or an aryl group.)

—Ar⁴—Z—Ar⁵— (4)

(In the formula, Ar⁴ and Ar⁵ are each independently a phenylene group or a naphthylene group; and Z is an oxygen atom, a sulfur atom, a carbonyl group, a sulfonyl group, or an alkylidene group.)

Examples of a halogen atom capable of being substituted with one or more hydrogen atoms in the groups represented by Ar¹, Ar², and Ar³ in General Formulae (1), (2), and (3) include a fluorine atom, a chlorine atom, a bromine atom, and an iodine atom.

The number of carbons of an alkyl group capable of being substituted with one or more hydrogen atoms in the groups represented by Ar¹, Ar², and Ar³ in General Formulae (1), (2), and (3) is preferably 1 to 10. Specific examples of the alkyl group include a methyl group, an ethyl group, an n-propyl group, an isopropyl group, an n-butyl group, an isobutyl group, a sec-butyl group, a tert-butyl group, an n-hexyl group, an n-heptyl group, a 2-ethylhexyl group, an n-octyl group, an n-nonyl group, and an n-decyl group.

As an example of an aryl group capable of being substituted with one or more hydrogen atoms in the groups represented by Ar¹, Ar², and Ar³ in General Formulae (1), (2), and (3), the number of carbons thereof is preferably 6 to 20. Specific examples of the aryl group include a monocyclic aromatic group such as a phenyl group, an o-tolyl group, an m-tolyl group, or a p-tolyl group, and a condensed aromatic group such as a 1-naphthyl group or 2-naphthyl group.

In a case where one or more hydrogen atoms in the groups represented by Ar¹, Ar², and Ar³ in General Formulae (1). (2), and (3) are substituted with these groups, the numbers of substitutions thereof are each independently preferably 1 or 2 and more preferably 1, for each group represented by Ar¹, Ar², and Ar³.

The number of carbons of an alkylidene group in General Formula (4) is preferably 1 to 10. Specific examples of the alkylidene group include a methylene group, an ethylidene group, an isopropylidene group, a n-butylidene group, and a 2-ethylhexylidene group.

As the repeating unit represented by General Formula (1), a repeating unit in which Ar¹ is a 1,4-phenylene group (repeating unit derived from p-hydroxybenzoic acid) or a repeating unit in which Ar¹ is a 2,6-naphthylene group (repeating unit derived from 6-hydroxy-2-naphthoic acid) is preferable, and a repeating unit in which Ar¹ is a 2,6-naphthylene group is more preferable.

As a monomer forming the repeating unit represented by General Formula (1), 2-hydroxy-6-naphthoic acid, p-hydroxybenzoic acid, or 4-(4-hydroxyphenyl) benzoic acid is used, and a monomer in which a hydrogen atom of the benzene ring or the naphthalene ring thereof is substituted with a halogen atom, an alkyl group having 1 to 10 carbon atoms, or an aryl group is also used. In addition, an ester-forming derivative which will be described later may be used.

As the repeating unit represented by General Formula (2), a repeating unit in which Ar² is a 1,4-phenylene group (repeating unit derived from terephthalic acid), a repeating unit in which Ar² is a 1,3-phenylene group (repeating unit derived from isophthalic acid), a repeating unit in which Ar² is a 2,6-naphthylene group (repeating unit derived from 2,6-naphthalene dicarboxylic acid), or a repeating unit in which Ar² is a diphenyl ether-4,4′-diyl group (repeating unit derived from diphenyl ether-4,4′-dicarboxylic acid) is preferable. Particularly, as the repeating unit, a repeating unit in which Ar² is a 1,4-phenylene group or a repeating unit in which Ar² is a 1,3-phenylene group is more preferable.

As a monomer forming the repeating unit represented by General Formula (2), 2,6-naphthalenedicarboxylic acid, terephthalic acid, isophthalic acid, or biphenyl-4,4′-dicarboxylic acid is used, and a monomer in which a hydrogen atom of the benzene ring or the naphthalene ring thereof is substituted with a halogen atom, an alkyl group having 1 to 10 carbon atoms, or an aryl group is also used. In addition, an ester-forming derivative which will be described later may be used.

As the repeating unit represented by General Formula (3), a repeating unit in which Ar³ is a 1,4-phenylene group (repeating unit derived from hydroquinone, p-aminophenol, or p-phenylenediamine) and a repeating unit in which Ar³ is a 4,4′-biphenylylene group (repeating unit derived from 4,4′-dihydroxybiphenyl, 4-amino-4′-hydroxybiphenyl, or 4,4′-diaminobiphenyl) are preferable.

As a monomer forming the repeated unit represented by General Formula (3), 2,6-naphthol, hydroquinone, resorcin, or 4,4′-dihydroxybiphenyl is used, and a monomer in which a hydrogen atom of the benzene ring or the naphthalene ring thereof is substituted with a halogen atom, an alkyl group having 1 to 10 carbon atoms, or an aryl group is also used. In addition, an ester-forming derivative which will be described later may be used.

As the monomer forming the structural unit shown in Formula (1), (2), or (3), an ester-forming derivative is preferably used, in order to easily perform polymerization in a process of manufacturing polyester. This ester-forming derivative indicates a monomer including a group which promotes an ester formation reaction. As specific examples of the ester-forming derivative, a high reactive derivative such as an ester-forming derivative in which a carboxylic acid group in a monomer molecule is converted into an acid halide or an acid anhydride, an ester-forming derivative in which a hydroxyl group in a monomer molecule is converted into a lower carboxylic acid ester group is used.

A content of a repeating unit (1) of the liquid crystal polyester is preferably equal to or greater than 30 mol % and less than 100 mol %, more preferably 30 mol % to 80 mol %, even more preferably 40 mol % to 70 mol %, and particularly preferably 45 mol % to 65 mol %, with respect to a total content of 100 mol % of the repeating unit (1), a repeating unit (2), and a repeating unit (3).

A content of the repeating unit (2) of the liquid crystal polyester is preferably 0 mol % to 35 mol %, more preferably 10 mol % to 35 mol %, even more preferably 15 mol % to 30 mol %, and particularly preferably 17.5 mol % to 27.5 mol %, with respect to a total content of 100 mol % of the repeating unit (1), the repeating unit (2), and the repeating unit (3).

A content of the repeating unit (3) of the liquid crystal polyester is preferably 0 mol % to 35 mol %, more preferably 10 mol % to 35 mol %, even more preferably 15 mol % to 30 mol %, and particularly preferably 17.5 mol % to 27.5 mol %, with respect to a total content of 100 mol % of the repeating unit (1), the repeating unit (2), and the repeating unit (3).

That is, in the liquid crystal polyester, it is preferable that the content of the repeating unit (1) is 30 mol % to 80 mol %, the content of the repeating unit (2) is 10 mol % to 35 mol %, and the content of the repeating unit (3) is 10 mol % to 35 mol %, with respect to a total of 100 mol % of the repeating unit (1), the repeating unit (2), and the repeating unit (3). In the ranges of the values, in a case where the liquid crystal polyester includes two or more of (1), (2), and (3), it is necessary that the total of each content is less than 100 mol %.

In the liquid crystal polyester, in a case where the content of the repeating unit (1) is in the range described above, melt fluidity, heat resistance, or strength and rigidity are easily improved.

In the liquid crystal polyester, a ratio of the content of the repeating unit (2) and the content of the repeating unit (3) is shown as [content of the repeating unit (2)]/[content of the repeating unit (3)] (mol/mol), and is preferably 0.9/1 to 1/0.9, more preferably 0.95/1 to 1/0.95, and even more preferably 0.98/1 to 1/0.98.

The liquid crystal polyester includes a repeating unit each including 2,6-naphthylene group, as the repeating unit (1), the repeating unit (2), and the repeating unit (3).

In the liquid crystal polyester, the content of the repeating unit including a 2,6-naphthylene group is equal to or greater than 40 mol % with respect to a total of 100 mol % of all of the repeating units. In a case where the content of the repeating unit including a 2,6-naphthylene group is equal to or greater than 40 mol %, a resin composition to be obtained has further excellent fluidity at the time of melting process and is more suitable in processing of the electronic equipment housing having a minute grid structure.

The liquid crystal polyesters may include each independently one kind or two or more kinds of the repeating unit (1), (2), or (3). The liquid crystal polyester may include one kind or two or more kinds of a repeating unit other than the repeating units (1), (2), and (3), and the content thereof is preferably 0 mol % to 10 mol % and more preferably 0 mol % to 5 mol % with respect to a total of all repeating units.

In the liquid crystal polyester, it is preferable that a repeating unit in which X and Y each include an oxygen atom is included as the repeating unit (3), that is, a repeating unit derived from predetermined aromatic diol is included, because melt viscosity easily decreases with the content described above, and it is more preferable that only a repeating unit in which X and Y each include an oxygen atom is included as the repeating unit (3).

The liquid crystal polyester is preferably manufactured by causing melt polymerization of a raw material monomer corresponding to the repeating unit configuring the liquid crystal polyester, and causing solid-state polymerization of the obtained polymer (prepolymer). Accordingly, it is possible to manufacture high-molecular weight liquid crystal polyester having high heat resistance or strength and rigidity with excellent operability. The melt polymerization may be performed under the presence of a catalyst, and examples of the catalyst include a metal compound such as magnesium acetate, stannous acetate, tetrabutyl titanate, lead acetate, sodium acetate, potassium acetate, or antimony trioxide, and a nitrogen-containing heterocyclic compound such as N, N-dimethylaminopyridine or N-methyl imidazole, and the nitrogen-containing heterocyclic compound is preferably used.

A flow start temperature of the liquid crystal polyester is preferably equal to or higher than 270° C., more preferably 270° C. to 400° C., and even more preferably 280° C. to 380° C. By increasing the flow start temperature to be higher than the lower limit, it is possible to improve heat resistance or strength and rigidity of the liquid crystal polyester. On the other hand, by decreasing the flow start temperature to be lower than the upper limit, it is rare that a high temperature is necessary for melting, thermal deterioration easily occurs at the time of molding, or fluidity is deteriorated due to an increase in viscosity at the time of melting.

The flow start temperature is also referred to as a flow temperature, is a temperature indicating a viscosity of 4,800 Pa·s (48,000 poise), in a case where liquid crystal polyester is melted while increasing a temperature at a rate of 4° C./min under a load of 9.8 MPa (100 kgf/cm²) by using a capillary rheometer and extracted from a nozzle having an inner diameter of 1 mm and a length of 10 mm, and is a measure of molecular weight of the liquid crystal polyester (see “Liquid Crystal Polymers-Synthesis and Molding and Applications-”, edited by Naoyuki Koide, CMC Publishing Co., Ltd., Jun. 5, 1987, p. 95).

The liquid crystal polyester may be used alone or in combination of two or more kinds thereof.

(Filling Material)

A filling material included in the resin composition of the embodiment will be described.

In the embodiment, the resin composition includes a specific filling material, and thus, it is possible to apply sufficient strength to the electronic equipment housing after molding.

The filling material used in the resin composition of the embodiment may be an inorganic filling material or may be an organic filling material. The filling material may be a fibrous filling material or a plate-like filling material. Here, the fibrous filling material indicates that a size of the filling material in the most longitudinal direction is 10 times or greater than sizes in the other two directions, for example. The plate-like filling material indicates that, for example, in a case where a length direction and a width direction forming one plane of the filling material are set and the remaining direction is set as a thickness direction, both sizes in the length direction and the width direction are three times or greater than the size in the thickness direction.

The fibrous filling material may be a fibrous inorganic filling material. Examples of the fibrous inorganic filling material include a glass fiber; a carbon fiber such as a pan-based carbon fiber or a pitch-based carbon fiber; a ceramic fiber such as a silica fiber, an alumina fiber, or a silica alumina fiber; and a metal fiber such as a stainless steel fiber. Examples thereof include whiskers such as potassium titanate whiskers, barium titanate whiskers, wollastonite whiskers, aluminum borate whiskers, silicon nitride whiskers, and silicon carbide whiskers.

The filling material used in the resin composition of the embodiment is preferably the fibrous inorganic filling material among those, and a glass fiber or a carbon fiber is preferable, among the fibrous inorganic filling materials.

As an example of the glass fiber, a glass fiber manufactured by various methods such as a chopped glass fiber or a milled glass fiber is used.

The glass fiber may be used alone or in combination of two or more kinds thereof.

As an example of the carbon fiber, a pan-based carbon fiber using polyacrylonitrile as a raw material may be used, a pitch-based carbon fiber using coal tar or petroleum pitch as a raw material may be used, a cellulose-based carbon fiber using viscose rayon or cellulose acetate as a raw material may be used, or a vapor grown carbon fiber using hydrocarbon as a raw material may be used. As the carbon fiber, a pan-based carbon fiber which improves strength of the electronic equipment housing the most is particularly preferable.

The carbon fiber may be a chopped carbon fiber or a milled carbon fiber. The carbon fiber may be used alone or in combination of two or more kinds thereof.

A number average fiber diameter of the fibrous inorganic filling material is preferably 1 to 20 μm and more preferably 5 to 15 μm. Here, the number average fiber diameter is a value measured by an optical microscope. A number average fiber length of the fibrous inorganic filling material before being mixed in the liquid crystal polyester is selected in accordance with the shape of the electronic equipment housing to be injection-molded, and is preferably 50 μm to 10 mm, more preferably 1 to 9 mm, and even more preferably 2 to 7 mm. Here, the number average fiber length is a value measured by an optical microscope.

In the embodiment, the content of the filling material in the resin composition may be suitably adjusted within a range not negatively affecting the fluidity of the resin composition.

Specifically, the content thereof is preferably 15 parts by mass to 80 parts by mass and more preferably 40 parts by mass to 67 parts by mass with respect to 100 parts by mass of the liquid crystal polyester.

In the embodiment, in the resin composition, by setting the content of the filling material to be in the range, it is possible to apply sufficient strength to the electronic equipment housing after molding, while maintaining sufficient fluidity of the resin composition.

(Other Components)

In the embodiment, the resin composition may include components which do not correspond to the liquid crystal polyester and the filling material, within a range not negatively affecting the effects of the embodiment.

Examples of the other components include a filling material other than the filling material (hereinafter, may be referred to as “other filling materials”), additives, or resins other than the liquid crystal polyester (hereinafter, may be referred to as “other resins”).

The other components may be used alone or in combination of two or more kinds thereof.

The other filling material may be a plate-like filling material or a particulate filling material.

Here, a particulate state may be a shape such as a sphere, an ellipsoid, or a polyhedron, and is a shape in which a size in one direction does not exceed three times the sizes in the other two directions. Particularly, in the embodiment, a shape having a size of 0.1 to 1,000 μm is referred to.

The other filling material may be an inorganic filling material or an organic filling material.

Examples of the plate-like inorganic filling material include talc, mica, graphite, wollastonite, barium sulfate, and calcium carbonate. Mica may be muscovite, phlogopite, fluorophlogopite, or tetrasilicic mica.

Examples of the particulate inorganic filling material include silica, alumina, titanium oxide, boron nitride, silicon carbide, and calcium carbonate.

In the embodiment, in a case where the resin composition includes the other filling material, the content of the other filling material in the resin composition is preferably greater than 0 part by mass and equal to or smaller than 10 parts by mass with respect to 100 parts by mass of the liquid crystal polyester. In addition, the content of the other filling material is preferably greater than 0 part by mass and equal to or smaller than 8 parts by mass with respect to a total mass of 100 parts by mass of the resin composition.

Examples of the additive include a metering stabilizer, a release agent, an antioxidant, a thermal stabilizer, an ultraviolet absorber, an antistatic agent, a surfactant, a flame retardant, and a colorant.

In the embodiment, in a case where the resin composition includes the additive, the content of the additive in the resin composition is preferably greater than 0 part by mass and equal to or smaller than 5 parts by mass with respect to 100 parts by mass of the liquid crystal polyester. In addition, the content of the additive is preferably greater than 0 part by mass and equal to or smaller than 3 parts by mass with respect to a total mass of 100 parts by mass of the resin composition.

Examples of the other resins include a thermoplastic resin other than the liquid crystal polyester such as polypropylene, polyamide, polyester, polyphenylene sulfide, polyether ketone, polycarbonate, polyphenylene ether, polyether imide, or a fluororesin; and a thermosetting resin such as a phenol resin, an epoxy resin, a polyimide resin, or a cyanate resin.

In the embodiment, in a case where the resin composition includes the other resins, the content of the other resins in the resin composition is preferably greater than 0 part by mass and equal to or smaller than 20 parts by mass with respect to 100 parts by mass of the liquid crystal polyester. In addition, the content of the other resins is preferably greater than 0 part by mass and equal to or smaller than 15 parts by mass with respect to a total mass of 100 parts by mass of the resin composition.

In the embodiment, the resin composition can be manufactured by mixing the liquid crystal polyester, the filling material, and the other components used, if necessary, collectively or in appropriate order.

The resin composition of the embodiment is preferably a pelletized material by melting and kneading of the liquid crystal polyester, the filling material, and the other components used, if necessary, by using an extruder.

Since the resin composition including the liquid crystal polyester having excellent fluidity is used, it is possible to increase the projected area per gate and it is possible to mold the electronic equipment housing of the embodiment with a small number of gates. By performing the molding with a small number of gates, the number of weld lines decreases and sufficient strength is obtained even with a thin thickness.

<Bend Elastic Modulus>

In the electronic equipment housing of the embodiment, a value of a bend elastic modulus measured at least in one direction is 20 to 50 GpPa, and both values thereof measured at least in two directions including two approximately perpendicular directions are preferably 20 to 50 GpPa.

Here, an approximately plate-like portion having a size of 150×150 mm selected from a position not including the margin plate 12, the hole 13, or the cut-out 14 is cut out from the plate 11 of the housing to be a test piece, and a jig having a jig width of 150 mm was pressed in a certain direction. The bend elastic modulus in the direction is a value in a case where it is measured with a gauge length Z of 100 mm and a test speed of 2 mm/s, by the same measurement method as a three-point bending test.

<Molding Method of Electronic Equipment Housing>

The electronic equipment housing can be molded by an injection molding method.

Specifically, the number of gates is adjusted so that the projected area per gate which is obtained by dividing the projected area of the electronic equipment housing by the number of gates of the die at the time of the injection molding, becomes equal to or greater than 100 cm², and the die is filled with the resin composition in a molten state. As the die, a die in which the ratio of the projected area (cm²) per gate and the average thickness (cm) of the electronic equipment housing is equal to or greater than 1,000 (or size obtained by dividing the projected area (cm²) by the average thickness (cm) is equal to or greater than 1,000 cm) is used. After that, a molded body may be extracted after cooling and solidification.

A temperature of the extruder used in a case of manufacturing the electronic equipment housing of the embodiment varies depending on a monomer composition of the liquid crystal polyester used in the resin composition. In a case where the flow start temperature of the liquid crystal polyester is set as FT, the temperature is preferably in a range of FT to FT+120° C. and more preferably in a range of FT to FT+80° C. For example, in a case of liquid crystal polyester having FT of 280° C., the temperature of the extruder is preferably 280° C. to 400° C. and more preferably 280° C. to 360° C.

Since the temperature of the extruder is higher than FT, an excellent dispersion of the filler without the liquid crystal polyester is obtained. In addition, as the temperature of the extruder increases, it is possible to improve heat resistance, strength, and rigidity of the electronic equipment housing. On the other hand, by setting the temperature of the extruder to be equal to or lower than FT+120° C., a possibility of a deterioration in mechanical characteristics due to thermal deterioration is low, and by setting the temperature of the extruder to be equal to or lower than FT+80° C., the mechanical characteristics can be further suitably adjusted. The temperature of the extruder can be, for example, adjusted by a temperature of a cylinder nozzle at the time of the injection molding.

A temperature of the resin composition at the time of the molding of the electronic equipment housing of the embodiment varies depending on a monomer composition of the liquid crystal polyester used in the resin composition. In a case where the flow start temperature of the liquid crystal polyester is set as FT, the temperature is preferably in a range of FT to FT+120° C. and more preferably in a range of FT to FT+80° C. For example, in a case of liquid crystal polyester having FT of 280° C., the temperature of the extruder is preferably 280° C. to 400° C. and more preferably 280° C. to 360° C. The temperature of the resin composition can be, for example, adjusted by a cylinder temperature of an injection molding machine at the time of the injection molding.

By setting the temperature of the resin composition at the time of molding the electronic equipment housing to be equal to or higher than FT, the fluidity of the molten resin of the resin composition in the die can be ensured, and a pressure in a case where molten resins of the resin composition collide with one another is equal to or greater than a given value in a weld portion where resins filled from other gates collide with one another. Thus, a decrease in strength of the electronic equipment housing in the weld portion hardly occurs. On the other hand, by setting the temperature of the resin composition to be equal to or lower than FT+120° C., a possibility of thermal deterioration due to retention of the molten resin in a cylinder of a molding machine is low, and by setting the temperature of the resin composition to be equal to or lower than FT+80° C., the mechanical characteristics can be further suitably adjusted.

An injection rate of the resin composition at the time of molding of the electronic equipment housing is preferably 200 to 500 cm³/s and more preferably 300 to 400 cm³/s. Specifically, in a case where a screw having ϕ 58 mm is used, an injection speed of the resin composition at the time of molding of the electronic equipment housing is preferably equal to or higher than 80 mm/s. By setting the injection rate as described above, a pressure in a case where the molten resins of the resin composition collide with one another in the weld portion increases, and thus, the strength of the weld portion increases.

### Examples

Hereinafter, the invention will be more specifically described with reference to examples and the invention is not limited to the following examples.

Manufacturing Method of Liquid Crystal Polyester A1

6-hydroxy-2-naphthoic acid (1034.99 g, 5.5 mol), 2,6-naphthalenedicarboxylic acid (378.33 g, 1.75 mol), terephthalic acid (83.07 g, 0.5 mol), hydroquinone (272.52 g, 2.475 mol, 0.225 mol greater than the total amount of 2,6-naphthalenedicarboxylic acid and terephthalic acid), acetic anhydride (1226.87 g, 12 mol), and 1-methylimidazole (0.17 g) as a catalyst were put into a reaction vessel including a stirring device, a torque meter, a nitrogen gas introduction pipe, a thermometer, and a reflux condenser, gas in the reaction vessel was substituted with nitrogen gas, the temperature was increased from room temperature to 145° C. for 15 minutes while stirring under a nitrogen gas flow, and reflux was performed at 145° C. for 1 hour. The temperature was increased from 145° C. to 310° C. for 3.5 hours while distilling byproduct acetic acid and unreacted acetic anhydride from the obtained product, and held at 310° C. for 3 hours, the content of the reaction vessel was extracted and cooled to room temperature. The obtained solid matter was pulverized to have a particle diameter of approximately 0.1 to 1 mm by a pulverizer, heated from room temperature to 250° C. for 1 hour under a nitrogen atmosphere, further heated from 250° C. to 310° C. for 10 hours, and held at 310° C. for 5 hours, thereby performing solid phase polymerization. After the solid phase polymerization, cooling was performed and powder-like liquid crystal polyester A1 was obtained. The flow start temperature of the liquid crystal polyester was 324° C.

The liquid crystal polyester and the like were supplied to a uni-directionally rotating twin-screw extruder having a screw diameter of 30 mm (“PCM-30HS” manufactured by Ikegai Corporation) with the proportion shown in Table 3, molded and kneaded at a temperature shown in Table 3, to be pelletized, and accordingly, pellets of resins 1 to 3 were obtained.

In Table 3, each symbol means as follows. In addition, numerical values in [ ] is a mixing proportion (parts by mass).
A1: liquid crystal polyester A1
P1: UBE Nylon 66 2020B manufactured by Ube Industries, Ltd.
Glass fiber: CS03-JAPx-1 (number average fiber diameter of 10 μm, number average fiber length of 3 mm) manufactured by Owens Corning Co., Ltd.
Carbon fiber: TR06UB4E (number average fiber diameter of 7 μm, number average fiber length of 6 mm) manufactured by Mitsubishi Rayon Co., Ltd.

TABLE 3

| | Resin | Filling | Molding temperature |
|---|---|---|---|
| | component | material | (° C.) |
| Resin 1 | A1 | Glass fiber | 350 |
| | [100] | [30] | |
| Resin 2 | A1 | Carbon fiber | 350 |
| | [100] | [30] | |
| Resin 3 | P1 | Carbon fiber | 280 |
| | [100] | [30] | |

<Molding of Electronic Equipment Housing>

A PC housing was manufactured as an example of the electronic equipment housing.

A PC housing 100A having the shape and the dimension shown in FIG. 2 was molded. In FIG. 2, L1=340, L2=230, L4=255, L5=210, L6=140, L7=50, L8=50, L9=85, L10=165, and L11=220. Each unit of these dimensions shown in FIG. 2 is mm.

In addition, the size L3 (not shown) of the average thickness of a PC housing 100A having the shape and the dimension shown in FIG. 2 is 0.13 cm.

Molding conditions are as follows.

| Molding machine: JSW450AD screw diameter of 66 mm | |
|---|---|
| Cylinder nozzle temperature: | resins 1 to 2 350° C. |
| | resin 3 280° C. |
| Hot runner manifold temperature: | resins 1 to 2 350° C. |
| | resin 3 280° C. |

Die temperature: 60° C.
Injection rate: 340 cm³/s
Resin used: each resin shown in Table 5
Number of gates: number of gates shown in Table 5
Gate diameter: 2 mm

PC housings 100B, 100C, and 100D respectively provided with the number of gates of 4, 3, and 12 were manufactured by using the PC housing 100A having the shape and the dimension shown in FIG. 2. The appearance of the PC housings 100B, 100C, and 100D after molding was visually confirmed and the number of generated weld lines was counted.

FIG. 3A shows the PC housing 100B having 4 gates. In FIG. 3A, L12=300, L13=150. L14=20, L15=45, L16=70, and L17=200. Each unit of these dimensions shown in FIG. 3A is cm. The positions shown at G1 to G4 of FIG. 3A are positions of the gates. In FIG. 3A, W schematically indicates a weld line. As shown in FIG. 3A, in a case where the number of gates is 4, four weld lines were generated. FIG. 3B is a view showing positions of gates of the PC housing 100B of FIG. 3A as a perspective view.

FIG. 4A shows the PC housing 100C having 3 gates. In FIG. 4A, L12=300, L18=150, L19=90, L20=45, L21=70, and L22=135. Each unit of these dimensions shown in FIG. 4A is cm. The positions shown at G of FIG. 4A are positions of the gates. In FIG. 4A, W schematically indicates a weld line. As shown in FIG. 4A, in a case where the number of gates is 3, two weld lines were generated. FIG. 4B is a view showing positions of gates of the PC housing 100C of FIG. 4A as a perspective view.

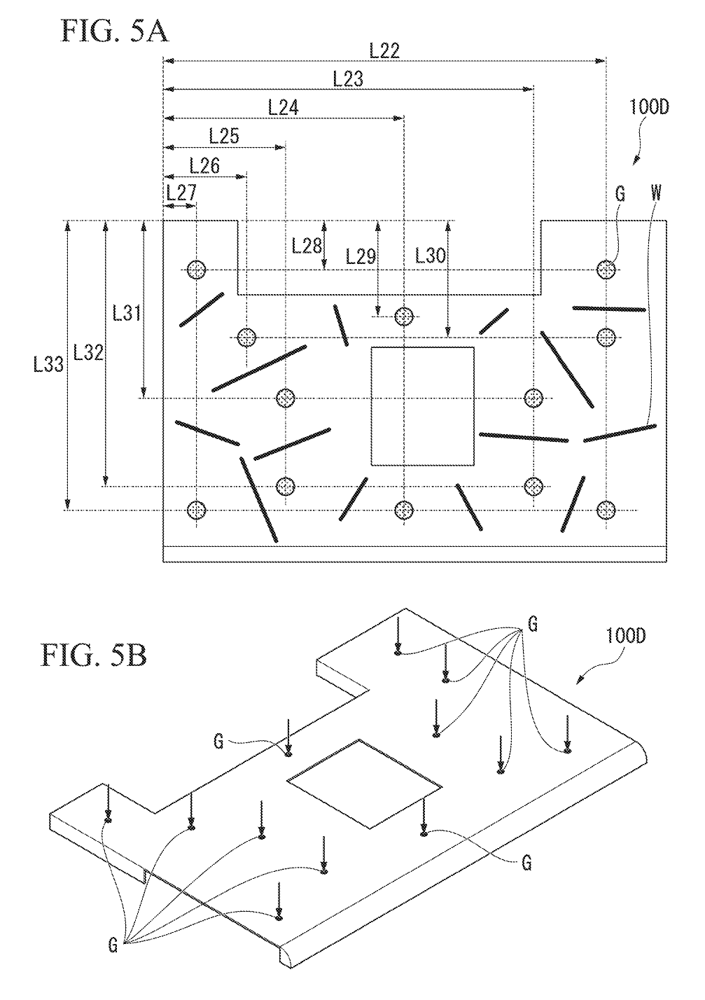

FIG. 5A shows the PC housing 100D having 12 gates. In FIG. 5A, L22=300, L23=250, L24=150, L25=90, L26=60, L27=20, L28=45, L29=70, L30=85, L31=151, L32=190, and L33=200. Each unit of these dimensions shown in FIG. 5A is cm. The positions shown at G of FIG. 5A are positions of the gates. In FIG. 5A, W schematically indicates a weld line. As shown in FIG. 5A, in a case where the number of gates is 12, 14 weld lines were generated. FIG. 5B is a view showing positions of gates of the PC housing 100D of FIG. 5A as a perspective view.

In the PC housing having the shape and the dimension shown in FIG. 2, a projected area per gate of each of the PC housings 100B, 100C, and 100D respectively having 4, 3, and 12 gates, and a ratio of the projected area per gate and the average thickness of the PC housing are as shown in Table 4.

TABLE 4

| | Number of gates | | |
|---|---|---|---|
| | 4 | 3 | 12 |
| Projected area per gate (cm²) | 150 | 200 | 50 |
| Rate of projected area and | 1153 | 1538 | 385 |
| average thickness | | | |

Table 5 shows molding results in a case where the PC housings having the gates shown in 100B, 100C, and 100D are molded to respectively have 4, 3, and 12 gates and the shape and the dimension shown in FIG. 2, by using the resins 1 to 3.

TABLE 5

| | | Number of gates | | |
|---|---|---|---|---|
| | Resin | 4 | 3 | 12 |
| Example 1 | Resin 1 | Moldable | Moldable | Moldable |
| Example 2 | Resin 2 | — | Moldable | Moldable |
| Comparative | Resin 3 | Not moldable | Not moldable | Moldable |
| Example 1 | | | | |

As shown in Table 5, in a case where the resin 1 was used, the PC housing could be molded, in all of the cases where the number of gates is 4, 3, and 12. In a case where the resin 2 was used, the PC housing could be molded, in all of the cases where the number of gates is 3, and 12.

In Examples 1 and 2 in which the resins 1 and 2 were used, the resin had sufficient fluidity, and thus, the PC housing could be molded, even in a case of a small number of gates which is 3 or 4.

Meanwhile, in a case where the resin 3 was used, the fluidity of the resin was not sufficient, and thus, the PC housing could not be molded, in a case where the number of gates was 3 or 4.

The molding can be performed even by using any resin, in a case where the number of gates is 12, but a large number of weld lines may be generated and a problem regarding strength may occur.

<Measurement of Bend Elastic Modulus>

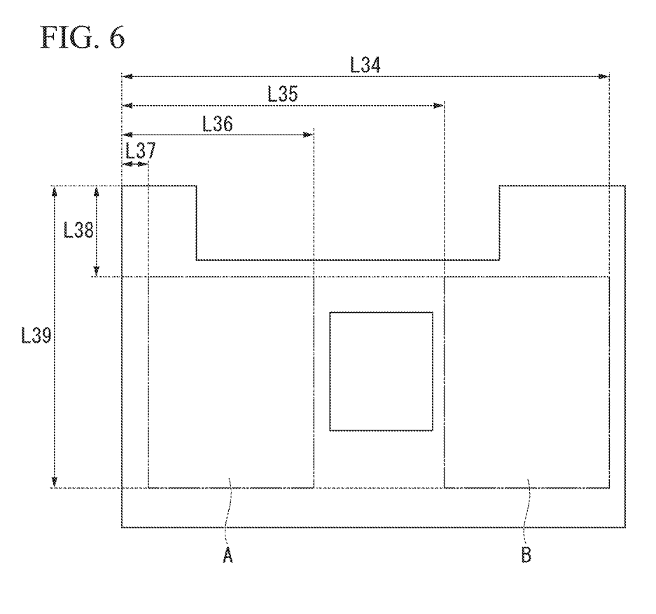

The PC housing having the dimension shown in FIG. 6 which was molded under the molding conditions shown in Table 6 was molded. A test piece A and a test piece B were cut out to have the dimension shown in FIG. 6. In FIG. 6, L34=330, L35=220, L37=15, L38=60, and L39=210. Each unit of these dimensions shown in FIG. 6 is mm.

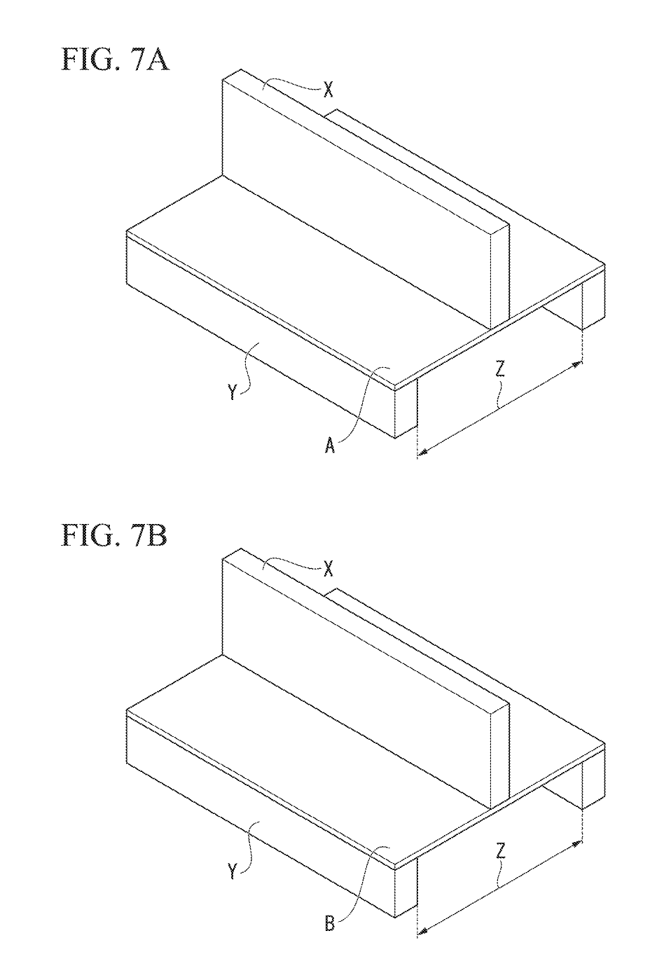

A jig X having a jig width 150 mm was pressed against the test piece A in a direction shown in FIG. 7A and a bending test was performed. In addition, the jig X having a jig width 150 mm was pressed against the test piece B in a direction shown in FIG. 7B and the bending test was performed. The bending test was performed by loading the test piece A or B on a support Y shown in FIGS. 7A and 7B and setting the gauge length Z as 100 mm and the test speed as 2 mm/s.

A bend elastic moduli (GPa) of the test pieces A and B at this time are shown in Table 6.

TABLE 6

| | Molding conditions | | Bend elastic moduli (GPa) | |
|---|---|---|---|---|
| | Resin | Number of gates | A | B |
| Example 3 | Resin 1 | 4 | 33 | 15 |
| Example 4 | Resin 2 | 3 | 42 | 28 |
| Comparative | Resin 3 | 12 | 17 | 21 |
| Example 2 | | | | |

As shown in Table 6, regarding the PC housing of Examples 3 and 4 molded by using the resins 1 and 2, excellent bend elastic modulus of the test pieces A and B was obtained. This may be because, in Examples 3 and 4, molding could be performed with a small number of gates which is 4 or 3, and thus, it was possible to prevent generation of weld lines and prevent a deterioration in strength due to generation of weld lines.

On the other hand, in Comparative Example 2, it is thought that, the molding was performed with 12 gates, and thus, a large number of weld lines was generated and strength was deteriorated due to a large number of weld lines.

### INDUSTRIAL APPLICABILITY

According to the invention, it is possible to provide an electronic equipment housing having a decreased number of weld lines and excellent strength even with a thin thickness.

### REFERENCE SIGNS LIST

11 Plate
12 Margin plate
13 Hole
14 Cut-out
15 Curved-surface margin plate
100 Housing
100A PC housing
A, B Test piece
G, G1 to G7 Gate
L1 to L39 Size
W Weld line
X Jig
Y Support
Z Gauge length

1. An electronic equipment housing obtained by injection molding of a resin composition including liquid crystal polyester and a filling material,
wherein a projected area per filling gate mark obtained by dividing a projected area of the electronic equipment housing by the number of filling gate marks of the resin composition on a surface of the electronic equipment housing is equal to or greater than 100 cm²,
a ratio obtained by dividing the projected area (cm²) per filling gate mark by an average thickness (cm) of the electronic equipment housing is equal to or greater than 1,000,
the average thickness of the electronic equipment housing is greater than 0.01 cm and equal to or smaller than 0.2 cm, and
the liquid crystal polyester has one or more repeating units selected from the group represented by General Formulae (1), (2), and (3).
—O—Ar¹—CO— (1)
—CO—Ar²—CO— (2)
—X—Ar³—Y— (3)
(in the formulae, Ar¹ is a phenylene group, a naphthylene group, or a biphenylylene group; Ar² and Ar³ are each independently a phenylene group, a naphthylene group, a biphenylylene group, or a group represented by General Formula (4); X and Y are each independently an oxygen atom or an imino group; and one or more hydrogen atoms in Ar¹, Ar², and Ar³ may be each independently substituted with a halogen atom, an alkyl group, or an aryl group or may not be substituted)
—Ar⁴—Z—Ar⁵— (4)
(in the formula, Ar⁴ and Ar⁵ are each independently a phenylene group or a naphthylene group; and Z is an oxygen atom, a sulfur atom, a carbonyl group, a sulfonyl group, or an alkylidene group)

2. The electronic equipment housing according to claim 1,
wherein the filling material is a glass fiber or a carbon fiber.

3. The electronic equipment housing according to claim 1,
wherein the liquid crystal polyester includes 30 mol % to 80 mol % of a repeating unit represented by General Formula (1), 10 mol % to 35 mol % of a repeating unit represented by General Formula (2), and 10 mol % to 35 mol % of a repeating unit represented by General Formula (3) with respect to a total of all repeating units constituting the liquid crystal polyester.
